(19) United States
(12) Patent Application Publication
(10) Pub. No.: US 2021/0168943 A1
(43) Pub. Date: Jun. 3, 2021

(54) Method for manufacturing a conductor structural element and conductor structural element

(71) Applicant: Schweizer Electronic AG, Schramberg (DE)

(72) Inventors: Thomas GOTTWALD, Dunningen (DE); Manuel MARTINA, Rottweil (DE)

(21) Appl. No.: 17/102,525

(22) Filed: Nov. 24, 2020

(30) Foreign Application Priority Data
Dec. 3, 2019 (DE) 102019132852.7

(51) Int. Cl. H05K 3/32; H05K 1/18; H05K 3/18

(52) U.S. Cl. CPC H05K 3/32; H05K 2203/166; H05K 3/188; H05K 1/186

(57) ABSTRACT

A conductor structural element includes an electronic component which is inserted into a dielectric layer and connected to a conductor pattern structure consisting of an electrically conductive material applied to an electrically conductive base layer by electroplating, wherein at least one contacting element of the electronic component is inserted into an assigned mounting area, which is formed as a recess in the conductor track structure, the at least one contacting element and the conductor track structure being connected to each other in an electrically conductive manner.

### TECHNICAL SUBJECT AREA

The present invention relates to a method for manufacturing a conductor structural element and to a conductor structural element.

### DESCRIPTION OF THE PRIOR ART

Various component mounting techniques are known from the prior art, which are also suitable for structures with embedded components/power semiconductors. The mounted components are embedded in a dielectric layer (prepreg layer). Such a method is known, for example, from WO 2011/079918 A2, which discloses a conductor structural element in which a component is inserted into a dielectric layer and connected to a conductor pattern structure, which is essentially flush with the surface. To make contact with the component, bump-type elements or copper pillars which protrude from the copper layer are provided, as is also known from DE 696 35 603 T2, for example.

DE 10 2016 206 607 A1 discloses electronic components with contacting elements designed as copper pillars.

### SUMMARY OF THE INVENTION

Based on the above, according to the invention a method for manufacturing a conductor structural element having the features as disclosed herein is proposed, as well as a conductor structural element having the features as disclosed herein.

The basic idea of the invention is to provide a mounting area which is formed as a left out space or recess on an electrically conductive base layer of a conductor structural element. The left out space is achieved by applying, in particular by electroplating, an electrically conductive layer which defines a recess, the shape, size and arrangement of which is chosen in such a way that it can accommodate at least one corresponding contacting element of an electronic component to be mounted. The application of the electrically conductive layer is implemented, for example, as mentioned above, by electroplating/galvanic deposition, but can also be implemented by other application processes, such as e.g. 3D printing or other processes familiar to the person skilled in the art.

Further advantages and embodiments of the invention are described in the the description and the enclosed drawing.

It goes without saying that the aforementioned features and those yet to be explained below can be applied not only in the corresponding specified combination, but also in other combinations or in isolation without departing from the scope of the present invention.

The invention is shown in the drawing highly schematically (and not true to scale) by reference to an exemplary embodiment and is described in detail in the following text with reference to the drawing.

### BRIEF DESCRIPTION OF THE DRAWINGS

FIG. 1 shows a plan view of an embodiment of a mounting area according to the invention.

FIG. 2 shows a plan view of a further embodiment of a mounting area according to the invention.

FIG. 3 shows the mounting area of FIG. 2 with a registration mark which is also applied thereon.

FIGS. 4 to 8 illustrate a sequence of a method according to the invention.

FIG. 9 shows a plan view of the mounting area produced according to the invention according to the viewing direction IX of FIG. 8.

FIGS. 10 to 12 show further method steps according to the invention.

FIG. 13 shows a view from the mounting side of a conductor structural element according to the invention directly before the mounting of an electronic component.

### DETAILED DESCRIPTION

Identical and similar features represented in the individual figures are indicated by the same reference signs.

FIG. 1 shows an example of an electrically conductive layer 13 (e.g. a copper layer) applied to an electrically conductive base layer 12, e.g. a copper film, according to the invention. The electrically conductive layer 13 can be produced, for example, by electroplating. In the electrically conductive layer 13 there is a mounting structure 14. The mounting structure 14 comprises, in particular, a mounting area 16 formed by leaving out a space in the electrically conductive layer 13. The left out space can be circular, for example, as shown in the embodiment of FIG. 1. The left out space can in principle have any shape, and it falls within the skilled person's knowledge to determine a suitable shape. A circular left out space is recommended in order to make the component mounting process as simple as possible.

The term plating is to be understood as the application of metal layers, in particular copper layers (copper plating), to a base layer or an existing layer structure, as is commonly known in circuit board technology. In particular, within the scope of the present invention, this includes the application of metallic pattern structures (referred to in the industry as pattern plating).

The mounting structure 14 can also comprise a conductor track 18, as shown, which is also formed in the plated-on layer 13. The conductor track 18 is conductively connected to a section 15 of the mounting structure 14. The section 15 surrounds the mounting area 16 and defines it. In the exemplary embodiment shown, the section 15 is formed as a circular ring which is connected integrally to the conductor track 18 and is widened compared to the latter (i.e. an outer diameter D of the circular ring 15 is greater than a width b of the conductor track 18). In the exemplary embodiment shown, an internal diameter d of the circular ring 15 (corresponding to the diameter of the mounting area 16) is also larger than the width b of the conductor track 18. The section 15 may have any other desired shape.

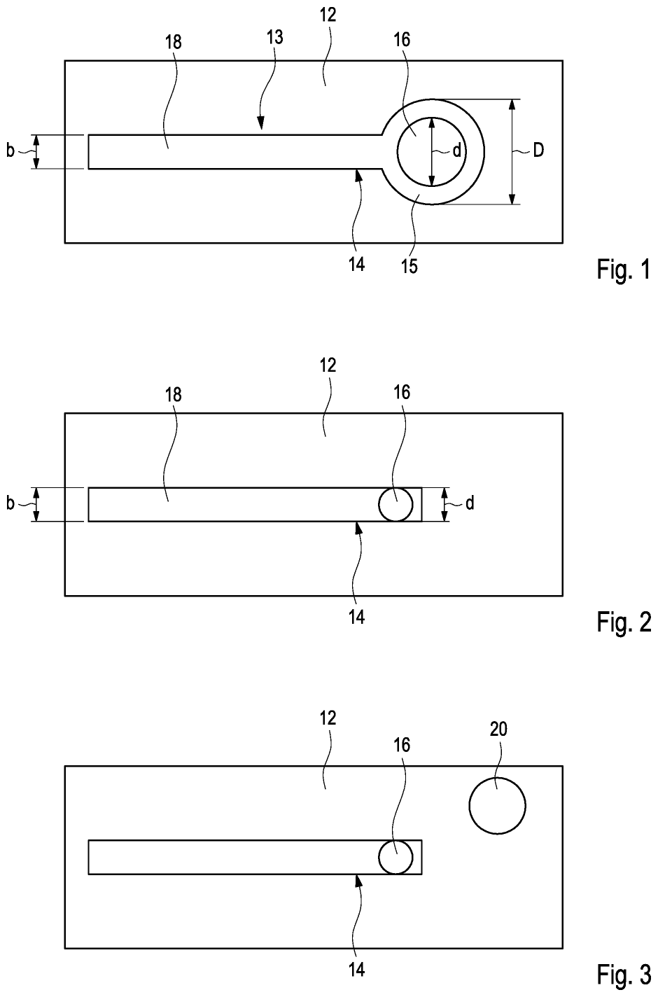

FIG. 2 shows a further exemplary embodiment of a mounting structure 14 produced according to the invention by plating onto an electrically conductive base layer 12, for example a copper film. In this exemplary embodiment, the left out mounting area 16 is formed as a circular recess in the conductor track 18. This means that the diameter d of the mounting area 16 is approximately equal to or less than the width b of the conductor track 18. Alternatively (not shown), the diameter of the mounting area can also be slightly larger than the width of the conductor track (in which case it is no longer a single-piece structure, but two separate regions).

FIG. 3 shows the exemplary embodiment of FIG. 2 with a registration mark 20 which is additionally plated onto the base layer 12. The registration mark 20 can be designed as a circular disc, as shown. However, it can also have other suitable shapes. The placement of the registration mark 20 can be positionally defined in relation to the mounting area 16. The application of a registration mark 20 is of course not limited to the exemplary embodiment of FIG. 2, but can also be provided in the exemplary embodiment of FIG. 1 and in any other possible design. The registration mark 20 is used by a placement robot in a known manner to align the intended placement of the mounting area 16 to the registration mark 20.

By reference to the following figures the method for manufacturing a conductor structural element according to the invention will now be described.

Firstly, an electrically conductive base layer 12, in particular a copper layer/copper film, is provided, onto which an electrically conductive structured layer 13, in particular of copper, is applied by means of pattern plating or other suitable application methods. The layer 13 applied in this way is designed such that it forms a left out or recessed mounting area 16. As illustrated in FIGS. 1 to 3, the structured layer 13 can also comprise a conductor track 18 or at least a conductor track section, by means of which a section 15 of the electrically conductive layer 13 at least partially surrounding the mounting area 16 (for the case in which a diameter of the mounting area 16 is larger than the width of the conductor track) and defining the same, is contacted (see also FIG. 6).

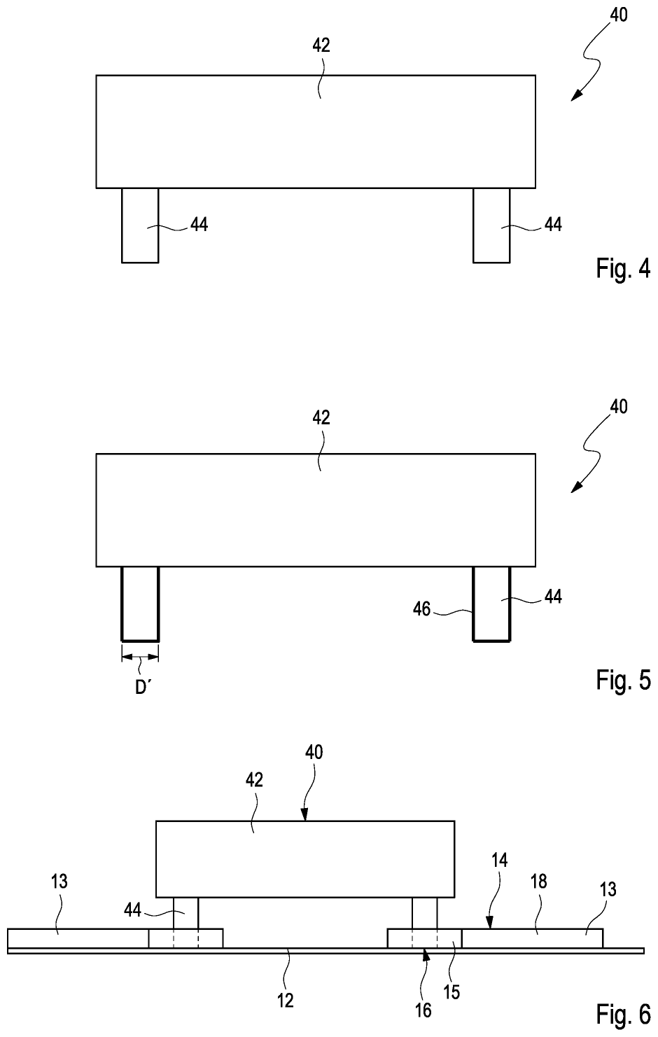

In addition, at least one electronic component 40 is provided. The electronic component can be, for example, a power semiconductor, a logic chip, an ASIC, etc. The electronic component 40 comprises a component body 42, on which contacting elements 44 are provided (see FIG. 4). The contacting elements can be constructed in particular as copper columns or copper bumps (known to the person skilled in the art by the term “copper pillar”). Other contacting means, such as e.g. solder coatings at the end of the copper pillars, are of course also possible. Solder in the context of the invention can mean classical solders based on Sn alloys, but also so-called diffusion solders (Au/Sn, AgSn . . . ), etc., which are completely converted into an intermetallic phase after the soldering process. The contacting elements 44 (as illustrated in FIG. 5) may be coated with an adhesion promoter 46, for example in the form of a brown-etched structure. Other forms of the adhesion promoter are familiar to the person skilled in the art.

In a next step, the at least one mounting structure 14 is mounted with one (or possibly more) component(s) 40, as illustrated in FIG. 6. In the case of the exemplary embodiment shown, two mounting structures 15 are shown, each with one mounting area 16, into which an electronic component 40 with two contacting elements 44 is inserted. The mounting areas 16 are formed in such a way that the respective diameter d of the mounting areas essentially corresponds to an external diameter D′ of the contact elements 44 to be inserted, in such a way as to allow an insertion/mounting with an exact fit. To secure the contacting elements 44 in the recesses forming the mounting areas 16, suitable joining means can be provided in the region of the contact surface, e.g. adhesives (particularly fast-curing adhesives, e.g. epoxy adhesives) or solder, or similar. The contacting elements 44 of the electronic component 40 and or the connecting agent can be heated directly before the component mounting, so that a better and faster joint is produced during the mounting process due to the heating. If solders are used, the soldering can be carried out during the component mounting by means of a heated placement head. Alternatively, the mounting can be performed at room temperature and the soldering can be carried out in a subsequent reflow soldering process.

If necessary, the mounted component can be stabilized after assembly by means of “underfilling”. In this process, the gap between the component 40 and the surface 12 is filled with an insulation material applied in liquid form and then cured.

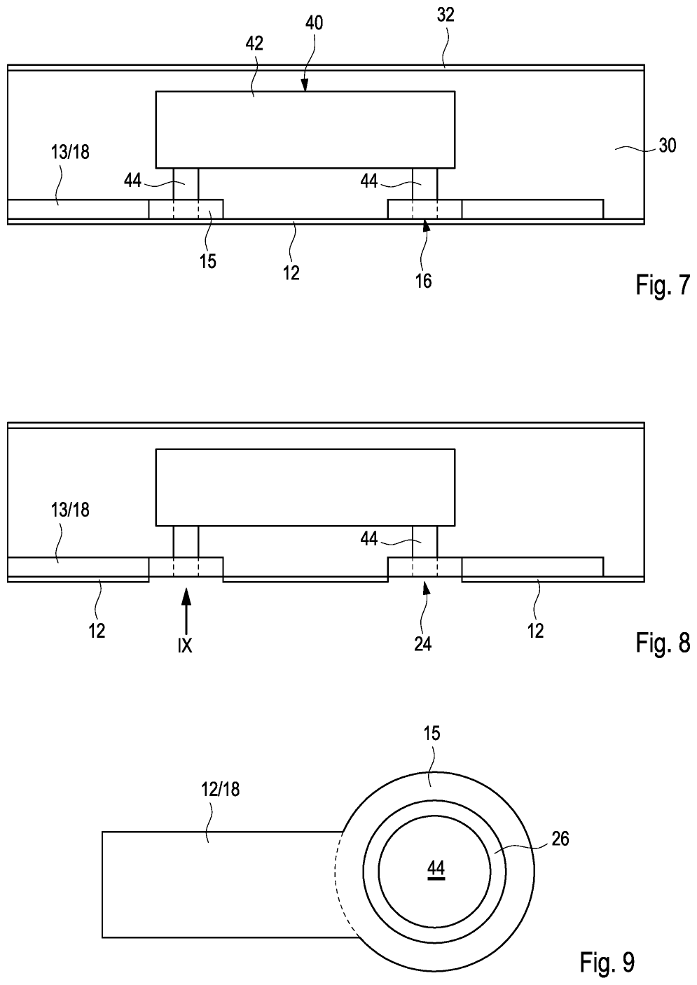

Then, layers of electrically insulating material 30 (such as prepreg material) are applied around and on the mounted component 40 and the resulting layer structure can be laminated with a cover layer 32 if required. Due to the lamination/compression process the resin contained in the electrically insulating material is liquefied and after curing forms a resin layer/dielectric layer 30 surrounding the mounted component 40 and the mounting structures 14 (see FIG. 7). If necessary, the assembled structure can be subjected to an adhesive promotion process once again. For example, the cover layer is a copper layer, e.g. as a copper film.

Finally, the base layer material (base copper) is removed either in the region of the contacts or completely, depending on the nature of the subsequent connection technique, i.e. the contacting elements 44 are exposed from the side of the base layer 12, as illustrated in the drawing of FIG. 8. The reference sign 24 indicates the location of such an exposed recess in the base layer 12, so that the contacts 44 are freely accessible. FIG. 9 shows a plan view of such an exposed contact 44 seen from a viewing direction IX marked with an arrow in FIG. 8. In FIG. 9, the reference sign 26 indicates the connection means (adhesive/solder). The exposure of the contacts, i.e. the removal of the base copper material in the region of the contacting elements 44, is carried out in a manner that is generally known to the person skilled in the art.

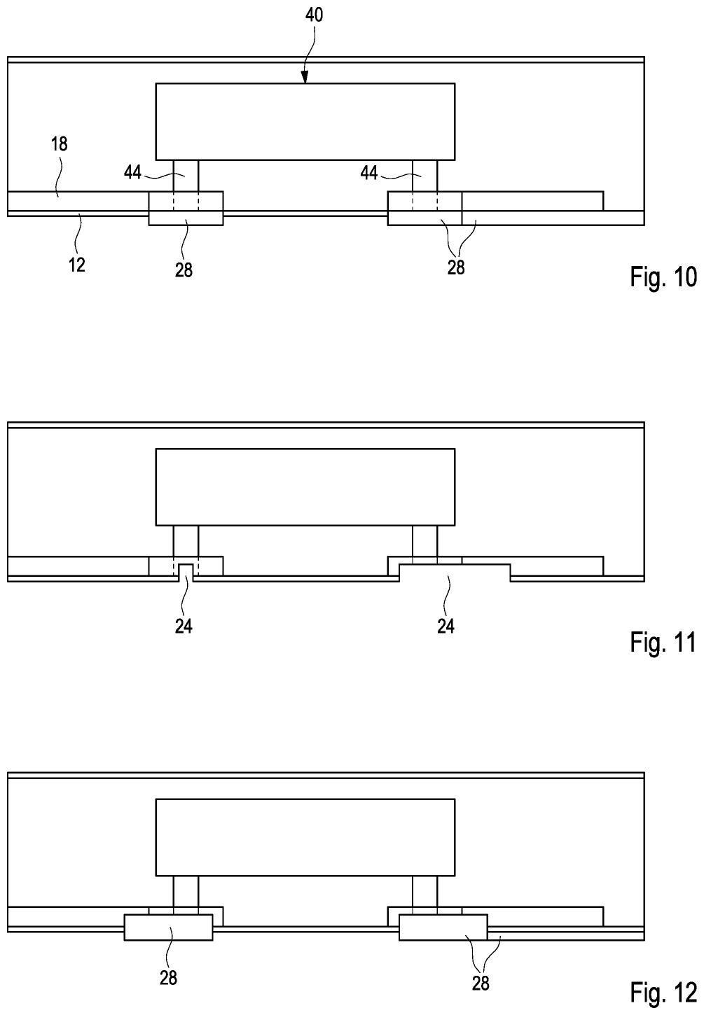

The contacts are then cleaned (for example, by laser, chemically or using a plasma), after which a conducting layer 28 is deposited (see FIG. 10). The conducting layer 28 can be applied either selectively (as in the region of the exposed contacting element (reference sign 44 and/or 26 and/or 15; see FIG. 9)) or over the whole surface (in addition to the region of the exposed contacting element 44 on the base layer 12 also, preferably over the conductor track 18). A copper layer/electrically conductive layer is then galvanically deposited on this conductive layer and on the exposed copper contacts. FIG. 10 shows a selective application to the left-hand contact element 44 in the drawing and a whole-surface application to the right-hand contacting element 44 in the diagram. This drawing is only intended for illustrative purposes, in reality, in each embodiment a decision on a form of the conductive layer plating will be made. Selective application of the conductive layer can be carried out, for example, by means of a conductive polymer (DMSE), while whole-surface application can be carried out, for example, by chemical deposition of copper.

Alternatively, the base layer 12 can be removed essentially completely. The contacting elements 44, 46 can then be connected to the conductive layer 13 (i.e. the layer sections or conductor tracks forming the recesses that receive the contacting elements) by means of a selectively operating application method (laser induced forward transfer method or metal sputtering with mask, 3D printing etc.).

As shown in FIG. 11, as an alternative to achieving a greater mechanical robustness of the layer, parts of the base copper 12 and parts of the plated-on layer 13 and the contacting element 44 can be removed, e.g. by laser ablation. The recesses 24 thus generated are then filled up by selective or whole-surface plating (see reference sign 28 in FIG. 12). Greater removal and higher plating increases the reliability of the conductive structure. The metal layer 28 is applied e.g. by galvanic deposition or by additive copper application using laser application methods (laser-induced forward transfer). In this process, copper is transferred from a substrate to the object to be coated by laser bombardment. The resulting outer layer thus produced can then be structured.

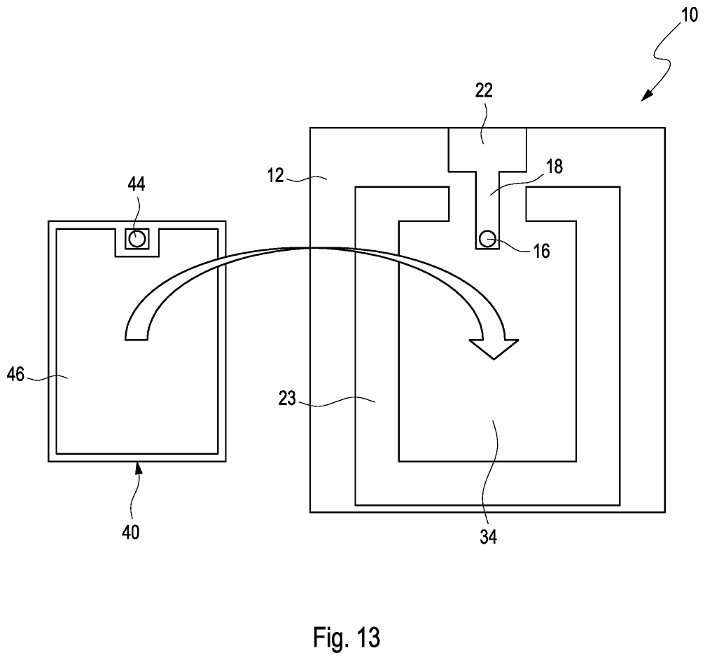

FIG. 13 shows a plan view of a detail of a component side of a conductor structural element 10 according to the invention, directly before the component mounting. The base copper 12, which is now exposed again after the removal (stripping) of the temporarily applied photoresist, and the copper structures that have been plated on, are now visible. In addition to the already described conductor track 18 and the mounting area 16 formed therein (see FIG. 2), these comprise a connection point 22 for contacting and a structured copper track 23, which is essentially rectangular in shape and surrounds a rectangular area 34 into which the conductor track 18 with the mounting area 16 protrudes. Alternatively, a design with a combined mounting and contact area (16, 34) can also be implemented.

In addition to the conductor structural element 10, an electronic component 40 to be mounted is also shown in top view. The electronic component 40 has a footprint congruent with the rectangular area 34 and is fitted with a contacting element 44, which, when the component 40 is inserted into the rectangular area 34, comes to rest in the left out or recessed mounting area 16 exactly as described above. A metallized area 46 (which can be a source contact) of the component 40 is positioned in the rectangular area 34.

Furthermore, also conceivable is a combination in which the contacting element 44 is contacted by means of the method according to the invention, while the area 46 is contacted conventionally after the process of embedding, i.e. with laser vias and through-contacts, for example. In principle, however, both contacts allow the application of the method according to the invention.

With the procedure according to the invention, the mounting rate can be significantly increased compared to conventional methods, e.g. thermal bonding, since the precise-fitting design of the contacting elements and mounting area allows highly accurate component mounting. The use of fast-curing connection means enables the mounted component to be quickly fixed in position, so that further processing is possible sooner. The copper pillars described as contacting elements can be implemented very precisely and in small dimensions, and the mounting can accordingly be carried out with high positional accuracy.

A conductor structural element according to the invention can be treated as a semi-finished product and then integrated into a printed circuit board, but it can also be formed as a stand-alone printed circuit board.

We claim:

1. A method for manufacturing a conductor structural element comprising the following steps:
providing an electrically conductive base layer;
applying an electrically conductive layer onto the base layer by electroplating, in such a way that at least one defined mounting area is left out;
choosing a shape, size and arrangement of the at least one defined mounting area in such a way that the at least one defined mounting area can accommodate at least one corresponding contacting element of an electronic component to be mounted;
mounting the electronic component by inserting the at least one corresponding contacting element thereof into the at least one mounting area in such a way that an electrically conductive connection is established between the at least one corresponding contacting element and the electrically conductive layer;
laying one or more layers of electrically insulating material and, if appropriate, one or more electrically conductive cover layers to form a layered structure;
laminating the layered structure; and
exposing the at least one corresponding contacting elements from a side of the base layer.

2. The method as claimed in claim 1, wherein the at least one defined mounting area is designed for receiving the at least one corresponding contacting element with an exact fit.

3. The method as claimed in claim 1, wherein a joining means is introduced into a recess forming the at least one defined mounting area before the mounting of the electronic component.

4. The method as claimed in claim 3, wherein the at least one corresponding contacting element or the joining means are heated before the mounting step and the mounting is carried out in a heated state.

5. The method as claimed in claim 1, wherein the step of exposing the at least one corresponding contacting element is made by at least partial removal of the base layer and, if appropriate, by removing parts of the electrically conductive layer or the at least one corresponding contacting element.

6. The method as claimed in claim 5, wherein after exposing the at least one corresponding contacting element, a conducting layer is applied selectively or over a whole surface and galvanically reinforced.

7. The method as claimed in claim 1, wherein the base layer is completely removed and the at least one corresponding contacting element and the conductive layer are connected using a selectively operating application process.

8. A conductor structural element, comprising:
an electronic component which is inserted into a dielectric layer and connected to a conductor pattern structure consisting of an electrically conductive material applied to an electrically conductive base layer by electroplating;
at least one contacting element of the electronic component is inserted into an assigned mounting area, which is formed as a left out space in a conductor track structure, the at least one contacting element and the conductor track structure being connected to each other in an electrically conductive manner.

9. The conductor structural element as claimed in claim 8, wherein the left out space is circular or rectangular.

10. The conductor structural element as claimed in claim 8, wherein the left out space is provided in the conductor track or is designed as a widening of the conductor track.

11. The conductor structural element as claimed in claim 8, wherein a registration mark is applied to the base layer by electroplating.

12. The conductor structural element as claimed in claim 8, wherein a portion of the base layer is removed at least in a region of the contacting element inserted into the mounting area to expose the contacting element.

13. The conductor structural element as claimed in claim 12, and further comprising a conducting layer applied on the exposed contacting element, reinforced with copper to connect the contacting element by means of a conductor structure.

14. A printed circuit board comprising a conductor structural element as claimed in claim 8 integrated therein.
